(19) United States
(12) Patent Application Publication
(10) Pub. No.: US 2019/0003922 A1
(43) Pub. Date: Jan. 3, 2019

(54) DEVICE AND METHOD FOR MOIRÉ MEASUREMENT OF AN OPTICAL TEST SPECIMEN

(71) Applicant: Carl Zeiss SMT GmbH, Oberkochen (DE)

(72) Inventors: Michael Samaniego, Oberkochen (DE); Peter Schade, Bad Duerkheim (DE); Michael Keil, Aalen (DE); Jaenker Bernd, Aalen (DE)

(21) Appl. No.: 16/101,739

(22) Filed: Aug. 13, 2018

Related U.S. Application Data
(63) Continuation of application No. PCT/EP2017/051759, filed on Jan. 27, 2017.

(30) Foreign Application Priority Data
Feb. 12, 2016 (DE) 10 2016 202 198.2

(51) Int. Cl. G01M 11/02; G03F 7/20; G03B 9/02

(52) U.S. Cl. CPC G01M 11/0242; G02B 27/60; G03B 9/02; G03F 7/706

(57) ABSTRACT

An apparatus for the moiré measurement of an optical test object includes a grating arrangement made of a first grating (25, . . . ) which is positionable in the optical beam path upstream of the test object and a second grating (11, . . . ) which is positionable in the optical beam path downstream of the test object, an evaluation unit having at least one detector (12, . . . ), for evaluating moire structures produced by superposition of the two gratings in a detection plane situated downstream of the second grating in the optical beam path, and at least one aperture stop (14, . . . ), by way of which the light distribution which was produced after the light exit from the second grating can be shadowed in a region-wise fashion such that only light of a subset of all field points on the second grating reaches the detection plane.

### CROSS REFERENCE TO RELATED APPLICATIONS

The present application is a continuation of International Application No. PCT/EP2017/051759, filed Jan. 27, 2017, which claims the priority under 35 U.S.C. § 119(a) of the German patent application DE 10 2016 202 198.2, filed on Feb. 12, 2016. The disclosures of both related applications are considered part of and are incorporated by reference into the disclosure of the present application in their respective entireties.

### FIELD OF THE INVENTION

The invention relates to an apparatus and a method for the moiré measurement of an optical test object.

### BACKGROUND

Microlithography is used for producing microstructured components such as, for example, integrated circuits or LCDs. The microlithography process is carried out in what is called a projection exposure apparatus, which comprises an illumination device and a projection lens. The image of a mask(=reticle) illuminated by way of the illumination device is in this case projected by way of the projection lens onto a substrate (e.g. a silicon wafer) coated with a light-sensitive layer (photoresist) and arranged in the image plane of the projection lens, in order to transfer the mask structure to the light-sensitive coating of the substrate.

In practice, there is a need to determine imaging aberrations, such as e.g. the distortion of the projection lens, as exactly as possible. In particular, the technique of moiré measurement is known in this respect, said technique comprising the projection of a first grating arranged in an object plane of the projection lens onto a second grating (also referred to as “moiré mask”) arranged in the image plane of the projection lens and the measurement of the light intensity respectively transmitted through this arrangement using an (e.g. camera-based) detector arrangement.

FIGS. 14 and 15 show merely schematic illustrations for explaining this principle. Here, the first grating situated in the object plane of the test object in the form of a projection lens 6 is denoted by “5”, the produced image of the test structures contained in the first grating 5 is denoted by “7”, and the second grating or the moiré mask is denoted by “8”. As a rule, the planes of the test structure image 7 on the one hand and of the second grating 8 or of the moiré mask on the other hand coincide and are depicted with spatial separation in FIG. 14 only for the purposes of better illustration. The light distribution 10 (which in accordance with FIG. 15 typically has a characteristic stripe pattern) obtained downstream of the second grating 8 or of the moiré mask in the light propagation direction is determined by way of a detector arrangement 9. Here, in the case of an appropriate design of the grating arrangement made of the first grating and the second grating, the transmitted light intensity in the case of aberration-free imaging is at a maximum, while it is reduced in the case where imaging aberrations of the projection lens 6 are present, because the light from bright regions of the test structures contained in the first grating 5 is increasingly incident on dark regions of the second grating 8 or of the moiré mask in the case of aberration-afflicted imaging.

Different measurement and evaluation methods based on the moiré measurement are known for ascertaining the respectively relevant imaging aberrations of the test object or projection lens. What these measurement and evaluation methods have in common is that signals used for individual field points are obtained in each case on the basis of averaging over a specific range. Here, in turn, signals at a plurality of field points are desirable in order to enable determination of the field profile of imaging aberrations, such as e.g. distortion.

However, one problem which occurs here in practice is that—as indicated in FIG. 16—an overlap of the respective light cones (denoted “9a” and “9b” in FIG. 16) which are assigned to different field points can occur due to the angle distribution of the light exiting from the test object or the projection lens 6 or the moiré mask 8, with the consequence that the light which is used in each case to evaluate different field points in part coincides in the respective detection plane. Causes of this effect are, among others, the light divergence present due to the angle distribution of the light exiting from the test object, the light divergence caused by diffraction at the moiré mask, and the divergence due to possible stray light.

However, attaining the highest possible field resolution in the moiré measurement is desirable in particular if, in a comparatively narrow image field—as is produced, for example, by a projection lens designed for EUV operation—additionally the highest possible number of mutually independent measurement signals are intended to be determined for ascertaining e.g. a field profile of the distortion.

### SUMMARY

Against the above background, it is an object of the present invention to provide an apparatus and a method for the moiré measurement of an optical test object, which allow improved field resolution in the ascertainment of imaging aberrations of the test object.

This object is achieved by the arrangements and methods described and claimed hereinbelow.

According to one formulation, an apparatus for the moiré measurement of an optical test object is provided, which comprises:
a grating arrangement made of a first grating which is positionable in the optical beam path upstream of the test object and a second grating which is positionable in the optical beam path downstream of the test object,
an evaluation unit having at least one detector, for evaluating moiré structures produced by superposition of the two gratings in a detection plane situated downstream of the second grating in the optical beam path; and
at least one aperture stop, by way of which the light distribution which was produced after the light exit from the second grating can be shadowed in a region-wise fashion such that only light of a subset of all field points on the second grating reaches the detection plane.

The According to another formulation, the inventors employ the concept of region-wise shadowing, in an apparatus for the moiré measurement of an optical test object such as e.g. a projection lens of a microlithographic projection exposure apparatus, of the light distribution which has been produced after the light exit from the moiré mask, or the second grating, using an aperture stop such that in each case only light of a subset of all field points reaches the detector. The selection of the field points which are measurable in a position of the aperture stop can here be such that light coming from different field points cannot superpose (wherein e.g. in one setting only every second, every third or every fourth field point is captured).

The aperture stop is preferably embodied here such that the relevant subset of all field points on the second grating which reaches the detection plane in each case is variably settable. In this way, it is possible during the course of performing a plurality of measurements successively (e.g. with displacement of the aperture stop into respectively different measurement positions) to realize capturing of all field points in a sequential measurement series.

As a result, the undesired superposition of the light cones coming from different field points of the second grating, or the moiré mask, in the optical beam path and consequently the undesired mixing of the information that is respectively assigned to said field points can be avoided hereby, and yet—in the course of performing a plurality of sequential measurement steps—ultimately the respectively desired total number of measurement points can likewise be attained for different positions of the aperture stop or different shadowing effected hereby with capturing of all field points on the second grating.

At the same time, due to the fact that said avoidance of the overlap of said light cones or of the mixing of the information associated with different field points of the moiré mask by respectively different shadowing is achieved in a plurality of measurement steps, the requirement to bring the detection plane as closely as possible to the second grating, or the moiré mask, is reduced. In other words, due to the aperture stop use in accordance with the invention, said mixing of the light cones that are associated with different field points can also be prevented in the case of comparatively greater distances between the moiré mask and the detection plane.

In accordance with one embodiment, the aperture stop is adjustable by way of displacement transversely to the light propagation direction and/or by way of rotation about an axis that is parallel with respect to the light propagation direction.

In accordance with one embodiment, the aperture stop is selectable from a plurality of aperture stops that differ from one another with respect to the shadowing that is effected respectively in the same position. The aperture stop is consequently arranged in the optical beam path to be correspondingly interchangeable. In comparison with the use of one and the same aperture stop that is merely varied in terms of its position between successive measurement steps, such use of different aperture stops in a plurality of measurement steps has the advantage that it is possible to simultaneously realize in a simple fashion a calibration and correction of any offsets, specifically by the ability to use matching field points of two different aperture stops in each case as “calibration locations”.

In accordance with one embodiment, the aperture stop, or the image produced thereof in the optical beam path, is situated away from the second grating by a distance of less than 100 μm, in particular less than 80 μm, more particularly less than 60 μm.

The aperture stop can be arranged in particular between the second grating and the detector. However, the invention is not limited thereto. Rather, the aperture stop in further embodiments can also be arranged, with respect to the light propagation direction, immediately upstream of the moiré mask, or the second grating, or immediately upstream or downstream of the first grating. The above-mentioned criterion, according to which the image of the aperture stop produced in the optical beam path is situated at a distance of less than 100 μm from the second grating, can furthermore also be realized by arranging the aperture stop in the region of an intermediate image plane of the test object, or the projection lens, or of the illumination device which is arranged upstream of it in the beam path. The placement of the aperture stop in the region of an intermediate image plane here has the advantage that the previously mentioned distance criterion is comparatively easy to fulfill, because generally no further optical element is located in said intermediate image plane.

In accordance with one embodiment, the detection plane has a distance from the second grating of less than 100 μm, in particular less than 80 μm, more particularly less than 60 μm, more particularly less than 40 μm, more particularly less than 10 μm, more particularly less than 5 μm, more particularly less than 1 μm, more particularly less than 200 nm.

In accordance with this embodiment, the distance between the moiré mask (i.e. the second grating, which is positioned downstream of the test object in the optical beam path) and a detection plane which follows in the optical beam path (and in which the superposition to be evaluated of the moiré mask with the first grating that is located upstream of the test object in the beam path takes place) is therefore selected to be comparatively sufficiently low. As a result, the respective area on which the light from a field point is distributed in the detection plane is kept small.

In this way, it is possible that only some of the field points have to be covered by the aperture stop with respect to the light coming therefrom in one and the same measurement step; in other words, a specific number of field points on the second grating can be measured at the same time, or in one and the same measurement step, and consequently a reduction of the required measurement time overall is achieved.

In some corresponding embodiments, which will be described in more detail below, the present invention also comprises various realizations of smaller distances between the moiré mask and the (e.g. camera-based) detector, wherein in each case e.g. manufacturing-technological challenges are addressed. In further embodiments, the present invention furthermore also comprises implementations with a comparatively large distance between the actual (e.g. camera-based) detector and the moiré mask, wherein, in the case of these implementations which will likewise be described in more detail below, a suitable optical signal transmission from the detection plane (arranged again at a small distance from the moiré mask) to the detector is realized in each case. Since in the case of this optical signal transmission in each case “crosstalk” between the signals which are associated with different field points can be avoided, it is consequently also possible here for a high field resolution to be realized while avoiding the problems as stated in the introductory part.

As a result, it is thus possible to achieve a sufficient field resolution in the moire measurement of the test object and also to ascertain a field profile of the relevant imaging aberrations, such as e.g. distortion, with particularly narrow image fields (for example in the case of a projection lens which is designed for EUV operation).

In accordance with one embodiment, the optical test object is a projection lens of a microlithographic projection exposure apparatus.

In accordance with one embodiment, the optical test object is designed for operation at an operating wavelength of less than 30 nm, in particular less than 15 nm.

In accordance with one embodiment, the detector has an array of light sensors.

In accordance with one embodiment, the detector has a sensor arrangement which is fiber-optically coupled to the detection plane.

In accordance with one embodiment, the apparatus has an auxiliary optical unit for imaging a light distribution obtained in the detection plane onto the detector.

In accordance with one embodiment, the apparatus furthermore has a quantum converter layer, which absorbs light of a first wavelength range that reaches the detection plane as primary light and emits secondary light of a second wavelength range, which differs from the first wavelength range.

In accordance with one embodiment, the quantum converter layer has in the first wavelength range a penetration depth of less than 10 μm, in particular less than 5 μm.

In accordance with one embodiment, the apparatus furthermore has a color filter layer, which at least partially filters out light that is not absorbed by the quantum converter layer.

According to another formulation, a method is provided for the moiré measurement of an optical test object using an apparatus having the above-described features, wherein, by way of the at least one aperture stop, the light distribution which was produced after the light exit from the second grating is shadowed in a region-wise fashion in a plurality of measurement steps such that in each case only light of a subset of all field points on the second grating reaches the detection plane.

In accordance with one embodiment, capturing of all field points is realized in a sequential measurement series by way of transitioning the aperture stop into different measurement positions and/or by interchanging the aperture stop.

With regard to advantages and advantageous configurations of the method, reference is made to the above explanations in association with the apparatus according to the invention.

Further configurations of the invention can be gathered from the description and the dependent claims.

The invention is explained in greater detail below on the basis of exemplary embodiments illustrated in the accompanying figures.

### BRIEF DESCRIPTION OF THE DRAWINGS

In the figures:

FIGS. 1A-1C, 2A, 2B, 3A, 3B, and 4-13 show schematic illustrations for explaining different embodiments of the present invention;

FIGS. 14-15 show schematic illustrations for explaining structure and functional principle of a conventional apparatus for the moiré measurement of an optical test object; and

FIG. 16 shows a schematic illustration for elucidating a problem which occurs in a conventional apparatus for the moiré measurement.

### DETAILED DESCRIPTION

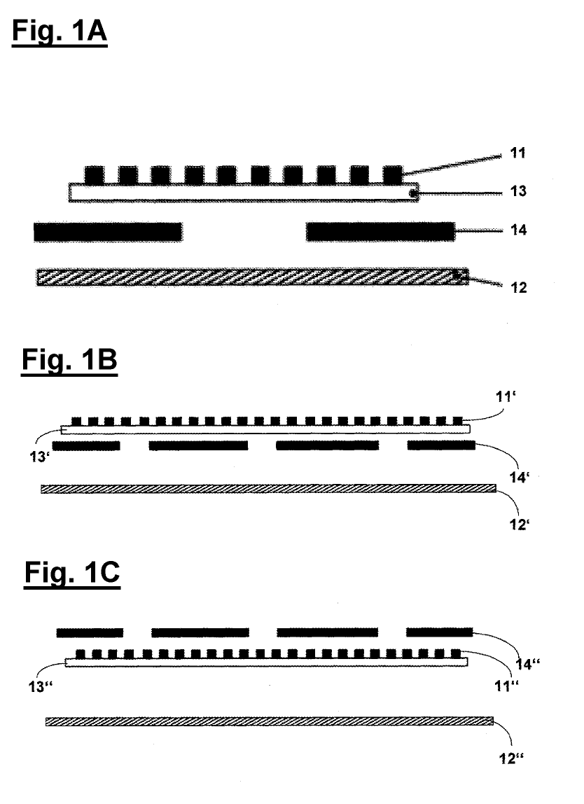

Provided according to the invention as per FIGS. 1A-1C is an aperture stop 14 (or 14′ or 14″ in FIG. 1B and FIG. 1C, respectively) which is displaceable transversely to the light propagation direction into different measurement positions.

It is possible via the aperture stop 14 for the light distribution which has come about after the light exit from the moiré mask, or the second grating 11, to be shadowed in a region-wise fashion such that in each case only light of a subset of all field points reaches the detector 12. The selection of the field points which are measurable in a position of the aperture stop 14 can here be such that light coming from different field points cannot superpose (wherein e.g. in one setting only every second, every third or every fourth field point is captured). In the course of performing a plurality of measurements successively, it is possible by displacing the aperture stop 14 into different measurement positions to realize capturing of all field points on the moiré mask, or the second grating, in a sequential measurement series.

Said aperture stop can be arranged, as per FIGS. 1A, 1B, between the moiré mask, or the second grating 11 (which is formed on a substrate 13), and the detector 12 and have, in particular as per FIG. 1B, a plurality of aperture openings. As per FIG. 1C, the aperture stop 14″ can also be arranged immediately upstream of the moiré mask, or the second grating 11″, with respect to the light propagation direction.

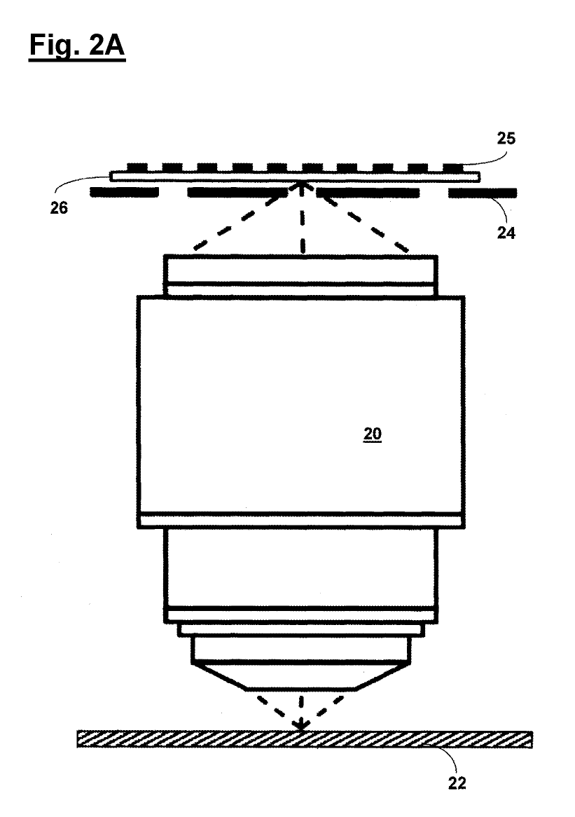

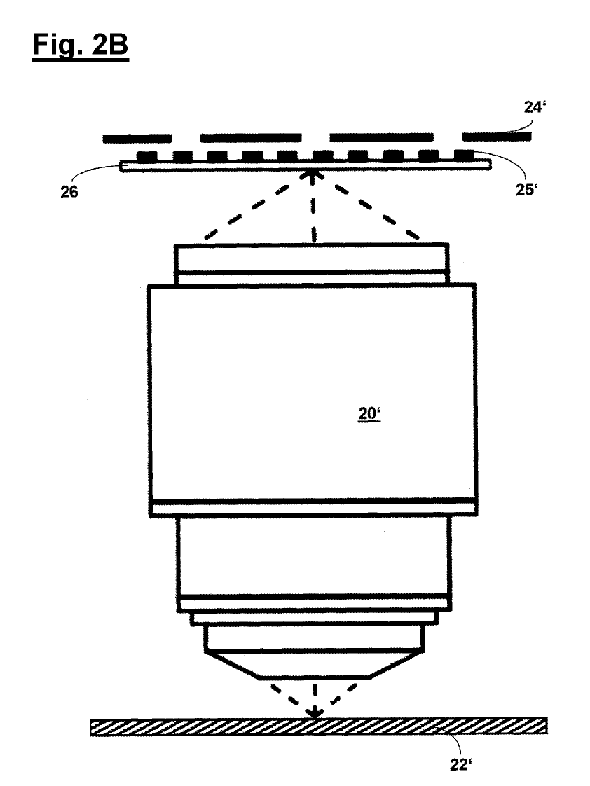

In addition, as per FIGS. 2A and 2B, the aperture stop 24 or 24′ can also be arranged immediately downstream of the first grating (FIG. 2A) or immediately upstream of the first grating (FIG. 2B), with respect to the light propagation direction. In FIGS. 2A and 2B, “26” and “26′” denote the substrate of the first grating, “20” and “20′” denote the test object, or the projection lens, and “22” and “22′” denote the detector.

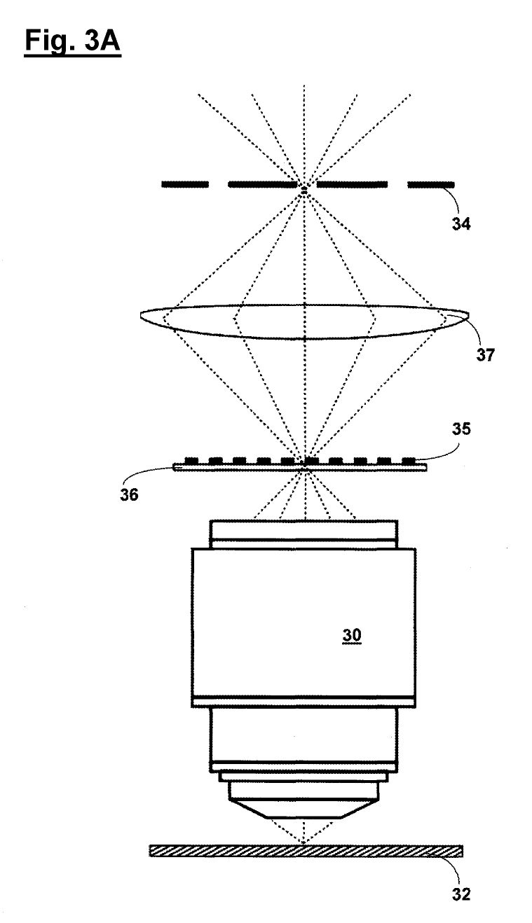

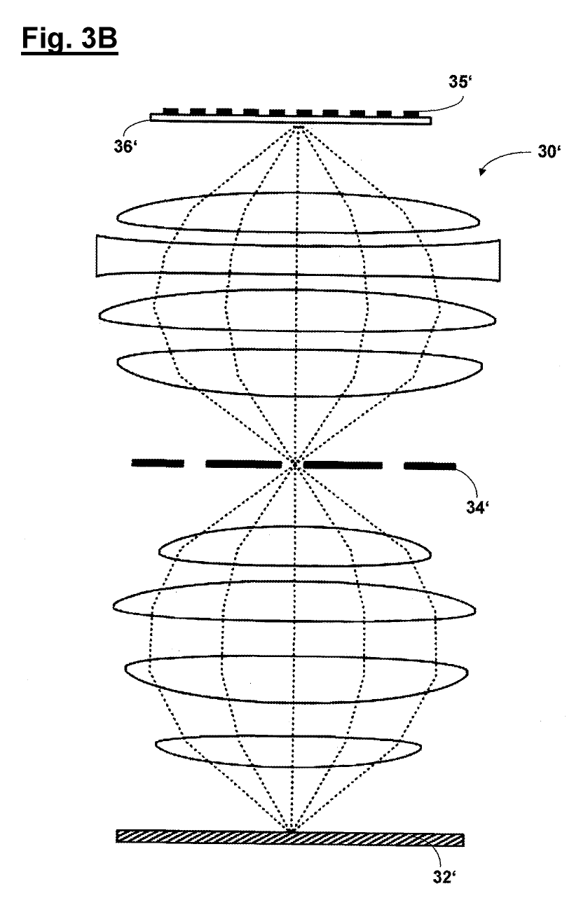

Generally speaking, the aperture stop, or the image produced thereof in the optical beam path, is situated away from the second grating, or the moiré mask, preferably by a distance of less than 100 μm, in particular less than 80 μm, more particularly less than 60 μm. In embodiments of the invention, this distance criterion can also be realized by arranging the aperture stop in the region of an intermediate image plane, as is schematically illustrated in FIGS. 3A and 3B. FIG. 3A shows the placement of an aperture stop 34 according to the invention in an intermediate image plane within the illumination device (of which merely one lens element 37 is indicated in FIG. 3A) that is located upstream of the first grating 35. Moreover, components which are analogous or have substantially the same function are denoted in FIG. 3A with reference numerals which are increased by “10” in relation to FIG. 2A. FIG. 3B likewise schematically shows, in strongly simplified fashion, the placement of an aperture stop 34′ according to the invention in an intermediate image plane within the test object, or projection lens 30′, wherein the first grating is here denoted with 35′ and the detector with 32′.

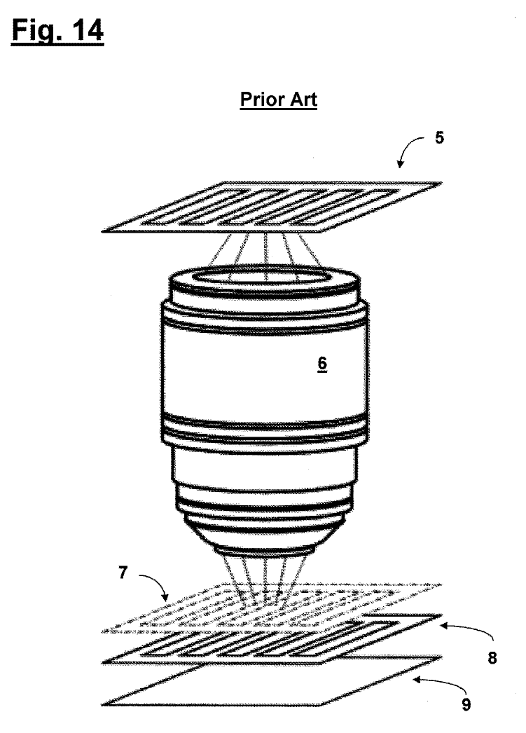

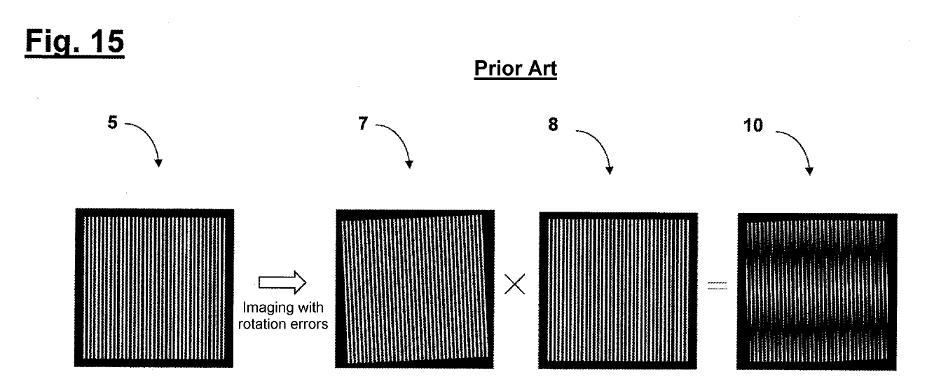

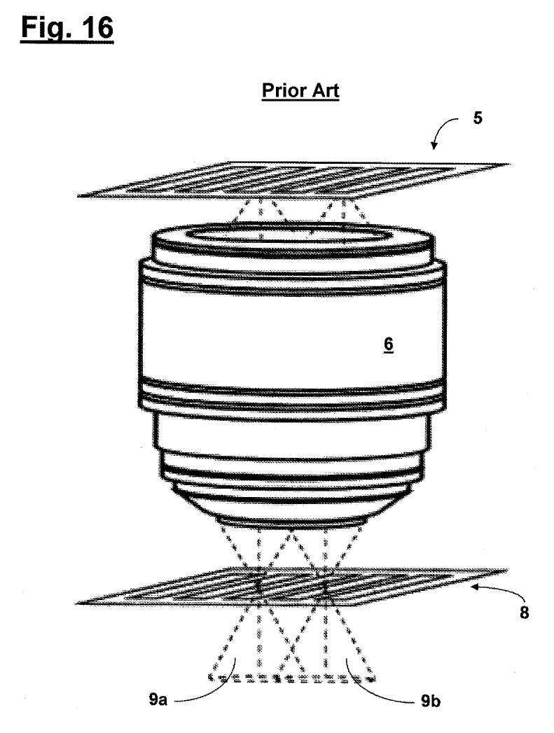

Furthermore described are, in each case proceeding from the basic setup for the moire measurement described with reference to FIGS. 14-16, various embodiments of the invention, in which in each case a small distance between detection plane and moiré mask is realized in order to realize a high field resolution while avoiding the problems described in the introductory section above (in particular the overlap of the light cones indicated in FIG. 16).

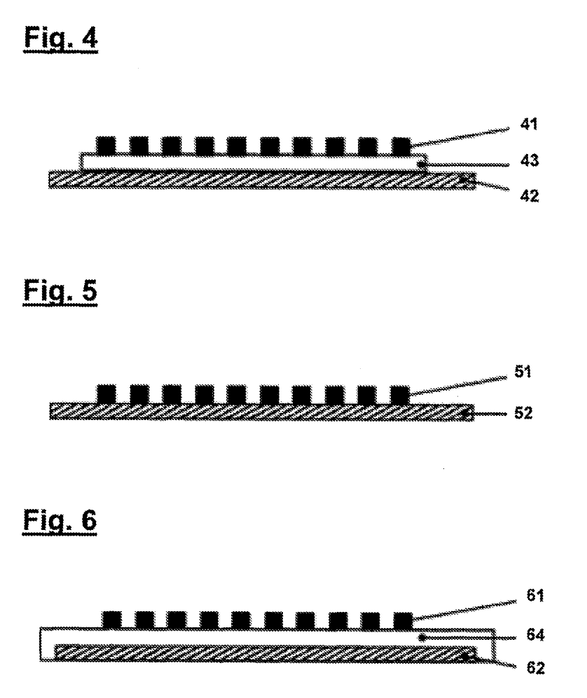

In the embodiments illustrated in FIGS. 4 and 5, this is done by realizing a correspondingly small distance between the respectively used (e.g. camera-based) detector and the moiré mask, while, in the embodiments illustrated in FIGS. 6-10, in each case a suitable optical signal transmission between the detection plane and the detector (farther away from the moiré mask in these examples) is realized.

FIG. 4 shows a first embodiment, in which a second grating 41, or the moiré mask, is applied to a substrate sheet 43 which is located directly on a detector 42 such that the distance between the moiré mask, or the second grating 41, and the detection plane is adjusted here via the thickness of the substrate sheet 43.

The substrate sheet 43 can be e.g. a glass membrane having an exemplary thickness of 25 μm. The substrate sheet 43 can be embodied here such that a reflection-reducing effect is attained to reduce undesired interference signals.

FIG. 5 shows a further embodiment, wherein components which are analogous or have substantially the same function are denoted by reference numerals increased by “10”. In contrast to FIG. 4, the moiré mask, or the second grating 51, as per FIG. 5 is applied directly to the surface of the detector 52 (which is designed as a camera chip in the exemplary embodiment). Applying the structures of the moiré mask, or of the second grating 51, can here already be a constituent part of the manufacturing process of the detector 52, or camera chip.

FIG. 6 shows a further embodiment, in which, in contrast to FIG. 5, the structures of the moiré mask, or of the second grating 61, are not applied directly to the detector 62, or camera chip, but to a protective layer 64 that is situated on the detector 62. Consequently, damage to the detector 62 during the manufacturing process (which can comprise a lithography process including etching steps or electron beam writing) can be prevented. The protective layer 64 can here be applied on the light-sensitive surface of the detector 62 only in region-wise fashion or on the entire light-sensitive surface of the detector 62. Furthermore, the protective layer 64 can also possibly enclose the entire detector 62, or camera chip. The thickness of the protective layer 64 can be selected in suitable fashion to adjust the desired distance between the moiré mask, or the second grating 61, and the detector 62, or the detection plane, and in addition to achieve a reflection reduction to eliminate undesired interference signals. In the exemplary embodiment, the protective layer 64 can be produced from quartz glass (SiO₂) and have a thickness ranging from 20 nm to 200 nm.

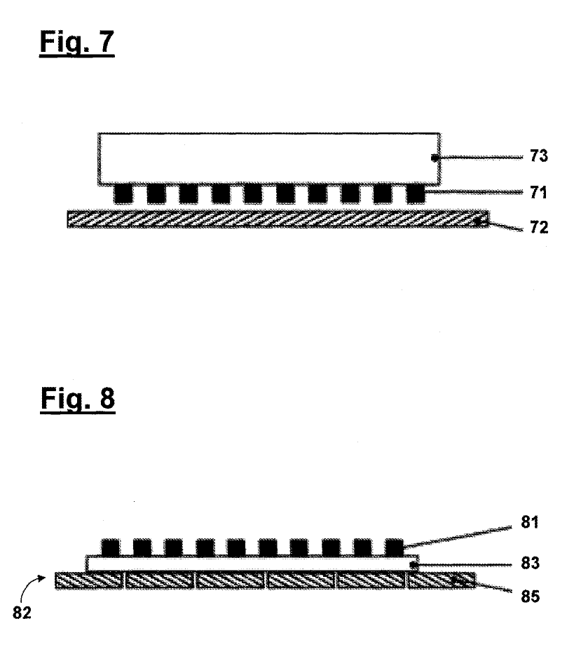

FIG. 7 shows a further embodiment, in which, in contrast to the previously described embodiments, the moiré mask, or the second grating 71, is arranged on that side of a transparent substrate 73 which faces away from the detector 72. As a consequence of this arrangement, the substrate 73 itself can have—despite the implementation, which is also present here, of a small distance between the moiré mask, or the second grating 71, and the detection plane—a relatively great thickness (e.g. of a few hundred micrometers (μm)), as a result of which increased stability of the arrangement can be realized.

FIG. 8 shows a further embodiment, in which the detector 85 has an array of light sensors, such as e.g. photodiodes, wherein otherwise a thin substrate 83 is again provided between the moiré mask, or the second grating 81, and the array 85 of light sensors which forms the detector 82. Hereby, the producibility can be improved with respect to a full-area camera chip as a detector, because achieved is a greater flexibility with respect to the respectively admissible manufacturing steps.

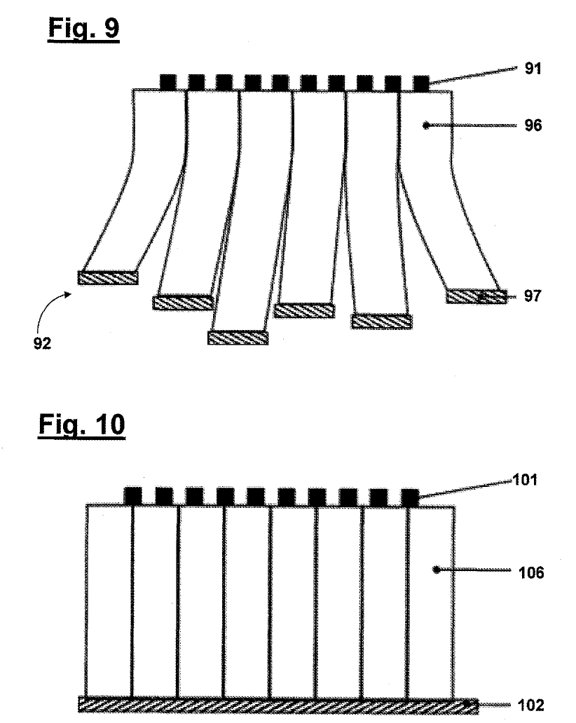

FIG. 9 and FIG. 10 each show embodiments in which the detector, or a sensor arrangement forming said detector, is fiber-optically coupled to the detection plane. As per FIG. 9 and FIG. 10, light is respectively received immediately downstream of the light exit from the moiré mask, or the respective second grating 91 or 101, wherein the respective optical signal is then guided via optical fibers 96 (as per FIG. 9) or a monolithic faceplate 106 (as per FIG. 10) to the respective detector 92 or 102, which itself can be located at a greater distance from the moire mask. Since the light which was recorded in the detection plane—again only at a short distance from the moiré mask—is fiber-optically transported to the respective detector 92 or 102, no mixing or crosstalk of the respective signals occurs.

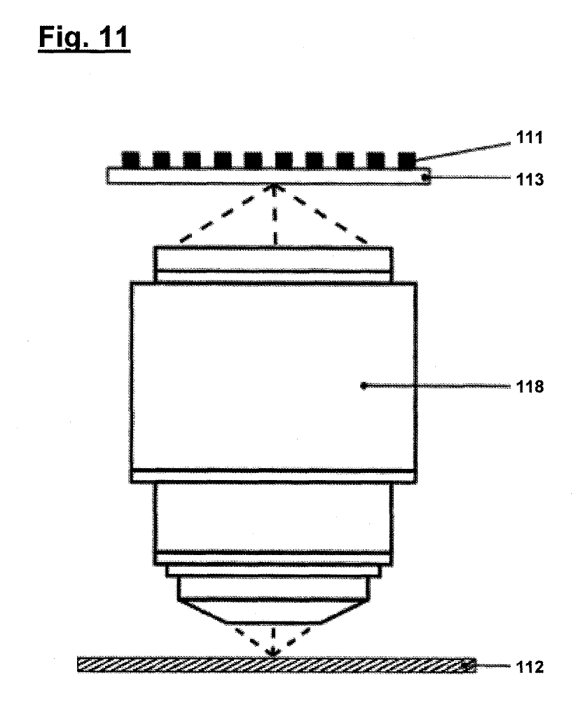

FIGS. 11, 12 and 13 show further embodiments in which, in contrast to the previously described examples, in each case one auxiliary optical unit in the form of an additional projection optical unit is used to image the light field which was acquired in the detection plane—once again located immediately downstream of the moiré mask—onto the detector 112, 122 or 132, which is farther away. The auxiliary optical unit 118, 128 or 138 is here embodied in each case such that it can transmit the full angle spectrum of the light which has been acquired downstream of the moiré mask, or the second grating 111, 121 or 131, or at least a representative portion of the respective angle spectrum.

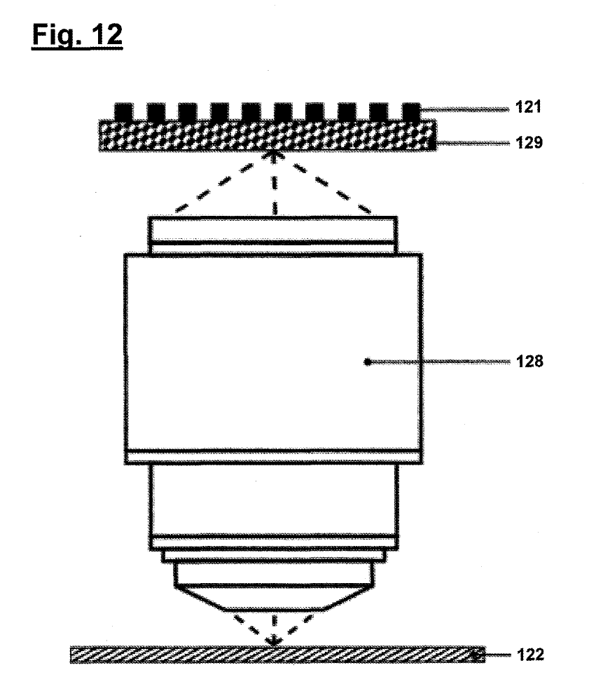

In contrast to FIG. 11, the moiré mask, or the second grating 121, as per FIG. 12 is situated on a quantum converter layer 129, which absorbs light of a first wavelength range that reaches the detection plane as primary light and emits secondary light of a second wavelength range, which differs from the first wavelength range.

In the exemplary embodiment, the quantum converter layer 129 can be produced, merely by way of example, of lithium glass, which has a penetration depth of less than 5 μm for wavelengths below 350 nm, and emits secondary light in a wavelength range between 360 nm and 500 nm. As a result, the angle distribution transmitted by the auxiliary optical unit 128 can be representative for the actual light intensity in the detection plane, and diffraction effects of the structures situated on the moiré mask can be left out of consideration. As a result of the low penetration depth of the material of the quantum converter layer 129 for the primary light and the absorption which consequently takes place after an optical path of only a few micrometers (μm) in this material, the distance between detection plane and moiré mask is effectively kept low even in this embodiment, because, as a result of the low penetration depth, primary light of different, adjacent field points cannot coincide.

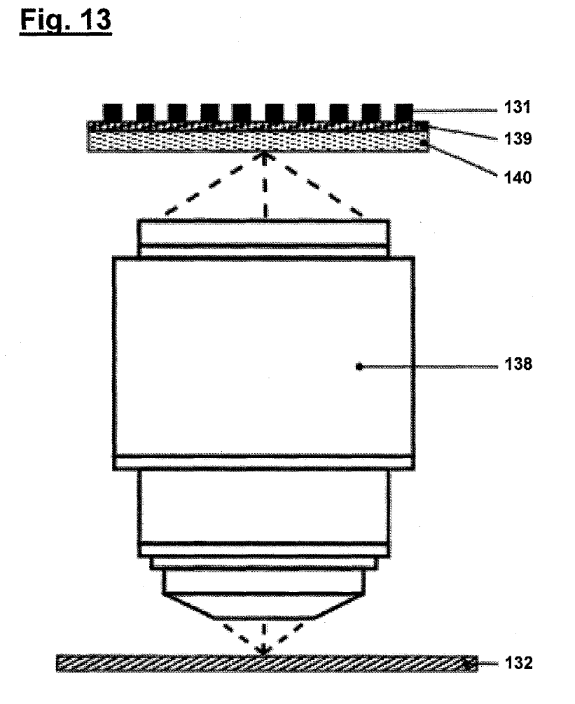

FIG. 13 shows a further embodiment, wherein components which are analogous or have substantially the same function are denoted by reference signs increased by “10” in relation to FIG. 12.

Compared to FIG. 12, an additional color filter layer 140, which at least partially filters out light that has not been absorbed by the quantum converter layer 139, is provided in the embodiment of FIG. 13. Hereby, account can be taken of the fact that, when using a comparatively thin quantum converter layer 139, the used (primary) light might have a penetration depth that exceeds the thickness of the quantum converter layer 139 (i.e. the effective distance between the detection plane and the moiré mask), wherein the unconverted primary light can here be eliminated by way of the color filter layer 140.

In further embodiments, an additional protective and/or anti-reflective layer for reducing undesired interference signals or for protective purposes can be used between the moiré mask and the quantum converter layer, between the quantum converter layer and the color filter layer, and/or in the beam path downstream of the color filter layer.

Even though the invention has been described on the basis of specific embodiments, numerous variations and alternative embodiments are apparent to a person skilled in the art, for example by combination and/or exchange of features of individual embodiments. Accordingly, such variations and alternative embodiments are concomitantly encompassed by the present invention, and the scope of the invention is restricted only within the meaning of the accompanying patent claims and the equivalents thereof.

What is claimed is:

1. An apparatus for the moiré measurement of an optical test object positioned in an optical beam path, comprising
a grating arrangement having a first grating positioned in the optical beam path upstream of the test object and a second grating positioned in the optical beam path downstream of the test object;
an evaluation unit having at least one detector, for evaluating moiré structures produced by superposition of the two gratings in a detection plane positioned downstream of the second grating in the optical beam path; and
at least one aperture stop, configured to shadow a light distribution produced after the optical beam exits the second grating in a region-wise fashion such that light of only a subset of all field points on the second grating reaches the detection plane.

2. The apparatus as claimed in claim 1, wherein the aperture stop is configured such that the subset of all the field points on the second grating which reaches the detection plane is variably settable.

3. The apparatus as claimed in claim 1 wherein the aperture stop is variably settable by displacement of the aperture stop transverse to the light propagation direction and/or by rotation of the aperture stop about an axis that is parallel with respect to the light propagation direction.

4. The apparatus as claimed in claim 1, wherein the aperture stop is configured as a plurality of aperture stops that are configured to differ from one another with respect to the shadowing effected in a stationary position.

5. The apparatus as claimed in claim 1, wherein the aperture stop, or the image produced in the optical beam path thereby, is situated away from the second grating by a distance of less than 100 μm.

6. The apparatus as claimed in claim 5, wherein the aperture stop, or the image produced in the optical beam path thereby, is situated away from the second grating by a distance of less than 10 μm.

7. The apparatus as claimed in claim 1, wherein the aperture stop is arranged between the second grating and the detector.

8. The apparatus as claimed in claim 1, wherein the detection plane has a distance from the second grating of less than 100 μm.

9. The apparatus as claimed in claim 8, wherein the distance from the detection plane to the second grating is less than 200 nm.

10. The apparatus as claimed in claim 1, wherein the optical test object is a projection lens of a microlithographic projection exposure apparatus.

11. The apparatus as claimed in claim 1, wherein the optical test object is configured for operation at an operating wavelength of less than 30 nm.

12. The apparatus as claimed in claim 1, wherein the detector comprises an array of light sensors.

13. The apparatus as claimed in claim 1, wherein the detector comprises a sensor arrangement which is fiber-optically coupled to the detection plane.

14. The apparatus as claimed in claim 1, further comprising an auxiliary optical unit configured to image a light distribution obtained in the detection plane onto the detector.

15. The apparatus as claimed in claim 1, further comprising a quantum converter layer, which absorbs light of a first wavelength range that reaches the detection plane as primary light and emits secondary light of a second wavelength range, which differs from the first wavelength range.

16. The apparatus as claimed in claim 15, wherein the quantum converter layer has in the first wavelength range a penetration depth of less than 10 μm.

17. The apparatus as claimed in claim 15, further comprising a color filter layer, which at least partially filters out light that has not been absorbed by the quantum converter layer.

18. A method for the moiré measurement of an optical test object using an apparatus as claimed in claim 1, comprising, with the at least one aperture stop, shadowing the light distribution which was produced after the light exits the second grating in a region-wise fashion in a plurality of measurement steps such that in each case only light of a subset of all field points on the second grating reaches the detection plane.

19. The method as claimed in claim 18, further comprising capturing all the field points on the second grating in a sequential measurement series by transitioning the aperture stop into different measurement positions and/or by interchanging aperture stops.
